(19) United States
(12) Patent Application Publication
(10) Pub. No.: US 2009/0117748 A1
(43) Pub. Date: May 7, 2009

(54) METHOD FOR MANUFACTURING A PHASE CHANGE MEMORY DEVICE CAPABLE OF IMPROVING THERMAL EFFICIENCY OF PHASE CHANGE MATERIAL

(75) Inventors: Dong Ryeol LEE, Ichon (KR); Chang Heon PARK, Ichon (KR); Hee Seung SHIN, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: Hynix Semiconductor, Inc., Ichon (KR)

(21) Appl. No.: 12/146,172

(22) Filed: Jun. 25, 2008

(30) Foreign Application Priority Data
Nov. 7, 2007 (KR) 10-2007-0113096

(51) Int. Cl. H01L 21/306

(52) U.S. Cl. 438/735; 257/E21.219; 257/E21.252

(57) ABSTRACT

A method for manufacturing a phase change memory device, capable of improving reset current characteristics of a phase change layer by preventing thermal loss of the phase change layer. An interlayer dielectric layer having a lower electrode contact is formed on a semiconductor substrate. A phase change layer and an upper electrode layer are sequentially formed on the interlayer dielectric layer. Then, an upper electrode and a phase change pattern are formed by etching predetermined portions of the upper electrode layer and the phase change layer using an etching gas having chlorine gas.

### CROSS-REFERENCES TO RELATED APPLICATION

The present application claims priority under 35 U.S.C. 119(a) to Korean application number 10-2007-0113096 filed on Nov. 7, 2007, which is incorporated by reference in its entirety as if set forth in full.

### BACKGROUND

1. Technical Field

The embodiments described herein relate to a method of manufacturing a phase change memory device, and more particularly, to a method of manufacturing a phase change memory device capable of improving thermal efficiency of phase change material, such as chalcogenide material.

2. Related Art

Portable communication appliances, in particular wireless portable communication devices, capable of processing large-scale information are becoming more and more prevalent. Such appliances require a memory device having high-speed, mass-storage, and low-voltage characteristics. Such a next-generation memory device should have a non-volatile function of a normal flash memory device, high-speed performance of an SRAM (static random access memory), and a high-integration function of a DRAM (dynamic RAM) while reducing power consumption thereof. Recent research in the area has identified several technologies that are candidates to fill this need, including FRAM (ferroelectric RAM), MRAM (magnetic RAM), PRAM (phase-change RAM), and NFGM (nano floating gate memory). Each of these technologies provides superior characteristics in terms of power consumption, data retention and write/read capability as compared with the normal memory device.

For example, among other things, a PRAM device has a simple structure and can be fabricated at a low cost. In addition, a PRAM device can be operated at high-speed. Accordingly, PRAM in particular is being actively studied as a next-generation memory device that can meet the above needs.

A PRAM has a phase change layer in which a crystal phase of the phase change layer is changed according to heat applied thereto. A chalcogenide compound (Ge—Sb—Te; GST) consisting of germanium (Ge), antimony (Sb), and tellurium (Te) is often used as the phase change layer for a conventional PRAM device. The phase of the phase change layer, e.g., the GST layer, may be changed from an amorphous phase to a crystal phase and vice versa via heat, which is generated as a result of current applied thereto. The GST represents high resistivity when the GST is in an amorphous phase. In contrast, the GST represents low resistivity when the GST is in a crystal phase.

Thus, it is possible to use the GST as a data storage medium of a memory device by utilizing the above resistivity characteristic. For example, the high and low resistivity of the two phases can be associated with the logic values “1” and “0” and can be detected via currents applied to the GST.

As mentioned above, however, low power consumption is another requirement, e.g., for portable appliances. Accordingly, various attempts have been pursued to reduce operational current of the GST layer, e.g., the reset current of the GST, so as to provide lower power consumption and higher integration.

To reduce the reset current, an area of a bottom electrode contact, which makes contact with the phase change layer, has been reduced such that the thermal efficiency can be increased.

FIG. 1 is a sectional view showing a conventional phase change memory device. Referring to FIG. 1, an interlayer dielectric layer 110 is formed on a semiconductor substrate 100 having a switching device, and then a contact hole (not shown) is formed by etching the interlayer dielectric layer 110 such that a predetermined portion of the switching device can be exposed through the contact hole. The contact hole may have a critical dimension corresponding to an exposure limit value, i.e., the contact hole may have a micro size. Then, a conductive layer is filled in the contact hole, thereby forming a lower electrode contact 115.

After that, a phase change layer 120, an upper electrode layer 130 and a hard mask layer 140 are sequentially formed on the interlayer dielectric layer 110 including the lower electrode contact 115. At this time, for example, the hard mask layer 140 may include silicon oxynitride (SiON).

Then, the hard mask layer 140, the upper electrode layer 130 and the phase change layer 120 are subject to a patterning process such that one phase change pattern 142 is associated with each lower electrode contact 115. Such a patterning process is often referred to as a node split of the phase change pattern. The patterning process is performed by using argon (Ar) and CF₄ gas, while applying source power of about 600 W and bias power of about 150 W.

Excessive etching is often used to achieve the required node-split, e.g., to form phase change pattern 142. Since the material used for the hard mask layer 140 is substantially identical to that of the interlayer dielectric layer 110, as shown in FIG. 1, an upper surface 110a of the interlayer dielectric layer 110 may be partially removed during formation of phase change pattern 142.

If the upper surface 110a of the interlayer dielectric layer 110 is partially removed, then a sidewall portion 144 of the lower electrode contact 115 may be exposed, which can lead to thermal loss when the phase change layer 120 heated, causing degradation of reset current characteristics of the phase change layer 120.

### SUMMARY

A method for manufacturing a phase change memory device capable of improving reset current characteristics of a phase change layer by preventing thermal loss of the phase change layer is described herein.

According to one aspect, an interlayer dielectric layer having a lower electrode contact is formed on a semiconductor substrate. A phase change layer and an upper electrode layer are sequentially formed on the interlayer dielectric layer. Then, an upper electrode and a phase change pattern are formed by etching predetermined portions of the upper electrode layer and the phase change layer using an etching gas having chlorine gas.

According to another aspect, an interlayer dielectric layer having a lower electrode contact is formed on a semiconductor substrate. A phase change layer, an upper electrode layer, and a hard mask layer are sequentially formed on the interlayer dielectric layer. A phase change structure is formed by etching predetermined portions of the upper electrode layer and the phase change layer using an etching gas having an argon gas and chlorine gas. Then, an encapsulating layer is formed on the semiconductor substrate such that the phase change structure is covered with the encapsulating layer.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a cross sectional view of a conventional phase change memory device; and

FIGS. 2 to 5 are sectional views illustrating a method for manufacturing a phase change memory device according to one embodiment.

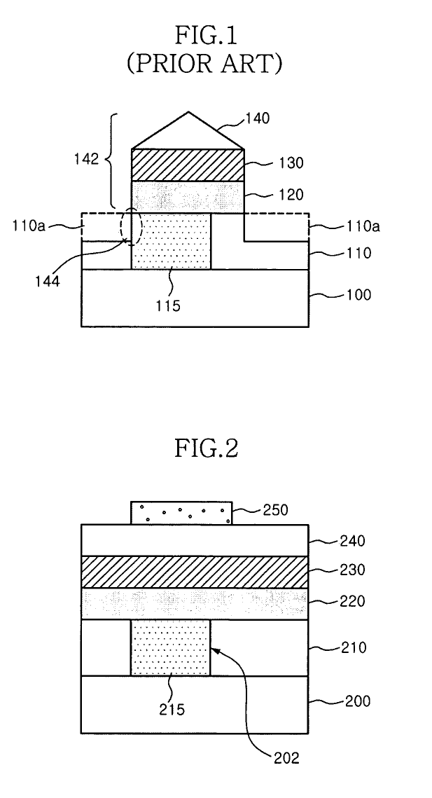

### DETAILED DESCRIPTION

Referring to FIG. 2, an interlayer dielectric layer 210 can be deposited on a semiconductor substrate 200 on which a switching device is formed. For instance, the switching device can include a vertical PN diode or an MOS transistor. The interlayer dielectric layer 210 can include a silicon nitride layer having superior heat-resistant characteristics. A contact hole 202 can then be formed in the interlayer dielectric layer 210 through a conventional photolithography and etching process, thereby exposing a predetermined portion of the switching device.

The contact hole can have a minimum critical dimension obtainable through the photolithography process.

Next, a conductive layer can be deposited on the interlayer dielectric layer 210 such that the contact hole 202 is sufficiently filled with the conductive layer. A lower electrode contact 215 can then be formed in the contact hole 202 through a planarization process, such as a chemical mechanical polishing process, applied to the conductive layer. The lower electrode contact 215 can, e.g., be formed from a conductive material having high resistivity, such as TiN or SiGe.

A phase change layer 220, an upper electrode layer 230 and a hard mask layer 240 can then be sequentially formed on the interlayer dielectric layer 210 and over the lower electrode contact 215. The phase change layer 220 can include GST-based material (chalcogenide material), and the upper electrode layer 230 can include Ti/TiN-based conductive material. The hard mask layer 240 prevents the phase change layer 220 from being deformed. For instance, the hard mask layer 240 can include silicon oxynitride (SiON).

A photoresist layer can then be formed on the hard mask layer 240 and patterned and etched, using conventional photolithography process for forming pattern 250. The photoresist pattern 250 can have a size sufficient for covering the lower electrode contact 215 and can define a phase change pattern.

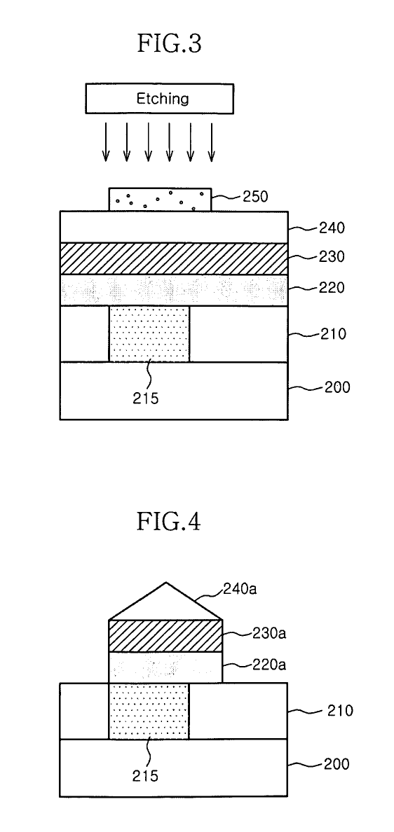

Referring to FIG. 3, the hard mask layer 240, the upper electrode layer 230 and the phase change layer 220 can then be etched using the photoresist pattern 250 as an etch mask, thereby forming a hard mask 240a, an upper electrode 230a and a phase change pattern 220a as illustrated in FIG. 4. The etching process can, e.g., be performed using argon (Ar) gas at a flow rate of about 100 to 140 sccm and a Cl₂ gas at a flow rate of about 20 to 40 sccm, while applying source power of about 1000 to 1200 W and bias power of about 50 to 100 W.

The combination of Ar and Cl₂ exhibits superior chemical reaction characteristics as compared with the combination of, e.g., Ar and CF₄, and provides superior etching selectivity relative to, e.g., a silicon oxynitride layer, as compared with other etching gases. Thus, an upper surface of the interlayer dielectric layer 210 can be protected from an etching gas even if the phase change layer 220 is subject to the excessive etching.

In addition, N₂ gas can also be used as in the etching gas. N₂ gas can improve linearity of the etching gas so that undesired side etching of the phase change layer 220, the upper electrode layer 230 and the hard mask layer 240 can be prevented. Depending on the embodiment, N₂ gas can be provided at, e.g., a flow rate of about 10 to 20 sccm.

After removing the photoresist pattern 250, a cleaning process can be performed to remove etching residues.

As can be seen in FIG. 4, the hard mask 240 has been thoroughly etched including portions of mask 240 under pattern 250; however, the upper surface of the interlayer dielectric layer 210 has not been etched.

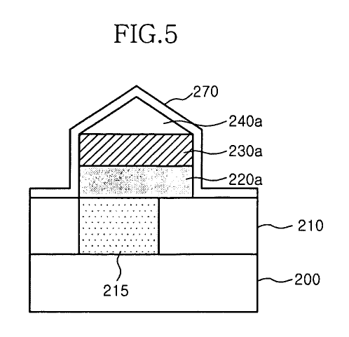

Referring to FIG. 5, an encapsulating layer 270 can then be formed to cover the hard mask 240a, the upper electrode 230a and the phase change pattern 220a. For instance, the encapsulating layer 270 can include a silicon nitride layer. The phase change pattern 220a can be sealed by the encapsulating layer 270 to improve the thermal efficiency during the phase change process.

According to the present invention, the chlorine-bearing etching gas is used when the etching process is performed to define the phase change pattern 220a. Since the chlorine-bearing etching gas represents superior etching selectivity relative to the interlayer dielectric layer including the silicon nitride layer as well as superior chemical reaction characteristics, undesirable etching of the interlayer dielectric layer can be mitigated. Further, by also using a nitrogen gas to improve linearity, undesirable side etching of the layers forming the phase change pattern can be prevented. As a result, the thermal efficiency of a phase change layer can be improved during a phase change process.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A method for manufacturing a phase change memory device, the method comprising:
forming an interlayer dielectric layer on a semiconductor substrate;
forming a lower electrode contact in the interlayer dielectric layer;
sequentially forming a phase change layer and an upper electrode layer on the interlayer dielectric layer; and
forming an upper electrode and a phase change pattern on the interlayer dielectric layer by etching predetermined portions of the upper electrode layer and the phase change layer using an etching gas including chlorine gas.

2. The method of claim 1, wherein the chlorine gas includes Cl₂ gas, and wherein the Cl₂ gas is provided at a flow rate of about 20 to 40 sccm.

3. The method of claim 1, wherein the etching gas further includes an argon (Ar) gas.

4. The method of claim 3, wherein the argon gas is provided at a flow rate of about 100 to 140 sccm.

5. The method of claim 1, wherein the etching gas further includes a nitrogen (N₂) gas.

6. The method of claim 5, wherein the N₂ gas is provided at a flow rate of about 10 to 20 sccm.

7. The method of claim 1, wherein source power of about 1000 to 1200 W and bias power of about 50 to 100 W are provided during the etching process.

8. The method of claim 1, wherein the interlayer dielectric layer includes a silicon nitride layer.

9. The method of claim 1, further comprising forming a hard mask layer on the upper electrode layer before the upper electrode layer and the phase change layer are etched.

10. The method of claim 9, wherein the hard mask layer includes a silicon oxynitride (SiON) layer.

11. The method of claim 1, further comprising forming an encapsulating layer on the phase change pattern and the upper electrode.

12. The method of claim 11, wherein the encapsulating layer includes a silicon nitride layer.

13. A method for manufacturing a phase change memory device, the method comprising:
forming an interlayer dielectric layer on a semiconductor substrate;
forming a lower electrode contact in the interlayer dielectric layer;
sequentially forming a phase change layer, an upper electrode layer, and a hard mask layer on the interlayer dielectric layer;
forming a phase change structure on the interlayer dielectric layer and the lower electrode by etching predetermined portions of the upper electrode layer and the phase change layer using an etching gas including an argon gas (Ar) and chlorine gas.

14. The method of claim 13, wherein the chlorine gas is Cl₂ gas, and wherein the Ar and Cl₂ gases are provided at flow rates of about 100 to 140 sccm and about 20 to 40 sccm, respectively.

15. The method of claim 14, wherein the etching gas includes nitrogen (N₂) gas.

16. The method of claim 15, wherein the N₂ gas is provided at a flow rate of about 10-20 sccm.

17. The method of claim 13, wherein source power of about 1000 to 1200 W and bias power of 50 to 100 W are provided during the etching process.

18. The method of claim 13, wherein the hard mask layer includes a silicon oxynitride (SiON) layer.

19. The method of claim 13, further comprising forming an encapsulating layer on the semiconductor substrate such that the phase change structure is covered with the encapsulating layer wherein the encapsulating layer includes a silicon nitride layer.

20. A method for manufacturing a phase change memory device, the method comprising:
forming an interlayer dielectric layer on a semiconductor substrate;
forming a lower electrode contact in the interlayer dielectric layer;
sequentially forming a phase change layer and an upper electrode layer on the interlayer dielectric layer; and
forming an upper electrode and a phase change pattern on the interlayer dielectric layer over the lower electrode contact by etching predetermined portions of the upper electrode layer and the phase change layer using an etching gas including a chlorine gas and a nitrogen (N₂) gas.
